(19) United States
(12) Patent Application Publication
(10) Pub. No.: US 2007/0080059 A1
(43) Pub. Date: Apr. 12, 2007

(54) Sputtering device

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/542,290

(22) Filed: Oct. 4, 2006

(30) Foreign Application Priority Data
Oct. 6, 2005 (JP) 2005-293094

(51) Int. Cl. C23C 14/00

(52) U.S. Cl. 204/298.01

(57) ABSTRACT

A sputtering device according to the present invention comprises at least a vacuum container, a substrate holder arranged in the vacuum container, plural sputtering cathodes each of which has a target for sputtering to a substrate installed on the substrate holder, wherein the plural sputtering cathodes are arranged so that center axes of the targets installed on the sputtering cathodes is inclined at specific angle against an axis of the substrate installed on the substrate holder, and a sputtering cathode unit constituted of the plural sputtering cathodes is held to the vacuum container rotatably around the axis of said substrate.

### BACKGROUND OF THE INVENTION

The present invention relates to a sputtering device having a plurality of sputtering cathodes which have targets for forming a thin film on a substrate respectively, wherein atoms or molecules of the targets are sputtered by means of colliding ionized gas to the targets to adhere them to the substrate.

JP 2002-20864 A discloses a sputtering device having a plurality of targets installed on respective cathodes and a substrate rotation device for rotating the round substrate on which the film should be formed around its center, wherein the plural targets are parallel to a surface of the substrate and centers of the plural targets are shifted to a center of the substrate, and further angle between a line extending through a center of target's surface and through a center of substrate's surface and a normal line of the substrate's surface is not less than 40°.

JP 2003-166055 A discloses a film forming device having a rotation substrate and a film forming source which face one another, wherein a film formation speed control member which controls film formation speed of a thin film formed on the substrate and a film thickness correction member which corrects thickness of the thin film formed on the substrate are provided between the substrate and the film forming source removably, characterized in that a means for measuring film thickness at plural measuring points along a radius of the rotation substrate is provided, that an opening creating film formation speed inclination inclined along the radius of the rotation substrate and a shutter for opening and closing the opening are provided, and that removal shutter controlling thin film on the substrate as the film thickness correction member.

JP 2004-339547 A invented by this inventor discloses a sputtering device comprising at least a substrate, a substrate holder holding the substrate, a target for forming thin film on the substrate, a sputtering cathode installing the target and magnets located behind the target, wherein an axis of the target is inclined to an axis of the sputtering cathode while the sputtering cathode is rotated to revolve the target to the substrate.

As seen from the above references, it was a usual large problem how to increase distribution of the film thickness on the substrate, and thus, various plans were carried out.

### SUMMARY OF THE INVENTION

The present invention provides a sputtering device having new constitution for increasing distribution of the film thickness on the substrate.

Therefore, the present invention provides a sputtering device comprising at least a vacuum container, a substrate holder arranged in the vacuum container, plural sputtering cathodes each of which has a target for sputtering to a substrate installed on the substrate holder, wherein: the plural sputtering cathodes are arranged so that center axes of the targets installed on the sputtering cathodes are inclined at specific angle against an axis of the substrate installed on the substrate holder, and a sputtering cathode unit constituted of the plural sputtering cathodes is held to the vacuum container rotatably around an axis of the substrate.

It is preferred that each of the sputtering cathodes is provided with a hood portion extending with a specific length in front of the target along a center axis of the target, and that an opening end portion of the hood portion is provided with a mean for modifying distribution blockading within a specific extent of the opening end portion.

It is preferred that the means for modifying distribution is constituted of a round metal plate having a diameter about half of the target and a support portion supporting the round metal plate and that a notch portion is provided in a portion positioned at a center axis side of the substrate.

Besides, it is preferred that the means for modifying distribution is constituted of a columnar portion having a bottom surface with a diameter about half of the target and extending with a specific length along a center axis of the target and a supporting portion supporting the columnar portion.

Furthermore, it is preferred that the hood portion has the opening end portion having a diameter about 1.5 times of the target and has a length same as a diameter of the target.

Moreover, each of the sputtering cathodes is that a center axis of the target is slanted at an angle of 45° to a center axis of the substrate installed on the substrate holder. Especially, it is more preferred that the angle is within 15° to 45°.

Besides, it is preferred that distance between the target and the substrate along the center axis of the target is within about three to four times of the diameter of the target.

Furthermore, it is preferred that the substrate hold on the substrate holder is arranged at a position shifting from a cross point where center axes of the targets cross.

According to the above constitution, since the sputtering cathode unit in which the plural sputtering cathodes are arranged so as to face to an approximately center position of the substrate can be rotated around a center axis of the substrate, every target can be sputtered in turns, so that an effect such that film thickness distribution can be increased is achieved.

Besides, it is possible to sputter every target simultaneously, and thus, an effect such that alloy thin film with good alloy degree in a film thickness direction can be formed is achieved.

Furthermore, according to providing the means for modifying distribution on the opening end portion of every sputtering cathode, sputtering particles in a center portion of the opening end portion can be restricted, so that it is possible to increase film thickness distribution.

Moreover, according to constituting the means for modifying distribution by the round metal plate having a diameter about half of the target and the supporting portion supporting the round metal plate and providing the notch portion on the position at the center axis side of the substrate, sputtering particles can be increased in the substrate center axis side of the slant sputtering cathode, so that the film thickness distribution in the whole of the substrate can be increased.

Besides, according to constituting the means for modifying distribution by the columnar portion having the bottom surface with the diameter about half of the target and extending with the specific length along the center axis of the target and the supporting portion supporting the columnar portion, a thick portion of the film thickness by the slant sputtering cathode unit can be smoothed, so that film thickness distribution in the whole of the substrate can be improved.

### BRIEF DESCRIPTION OF THE DRAWINGS

In the accompanying drawings, there are shown illustrative embodiments of the invention from which these and other of its objective, novel features, and advantages will be readily apparent.

In the drawings:

FIG. 1 is a schematic diagram of a sputtering device according to embodiments 1 and 2 of the present invention;

FIG. 2A is a front view of a distribution modifying plate according to embodiment 1 of the present invention and FIG. 2B is a side view of it;

FIG. 3 is a characteristic diagram showing film thickness distribution due to the distribution modifying plate according to embodiment 1 of the present invention;

FIG. 4A is a front view of a distribution modifying plate according to embodiment 2 of the present invention and FIG. 4B is a side view of it; and

FIG. 5 is a characteristic diagram showing film thickness distribution due to the distribution modifying plate according to embodiment 2 of the present invention.

### DETAILED DESCRIPTION OF THE PREFERRED EMBODIMENT

Hereinafter, the embodiments of this invention were explained by referring drawings.

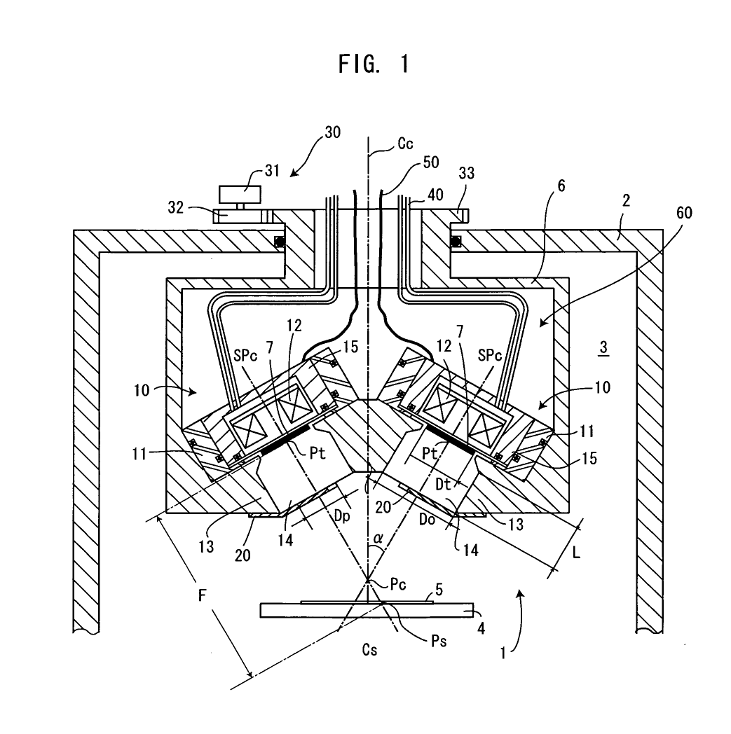

A sputtering device 1 shown in FIG. 1 is constituted of at least a vacuum container 2 defining a sputtering space 3, a substrate holder 4 holding a substrate 5 in the sputtering space 3, a sputtering cathode unit 60 held rotatably in the vacuum container 2 and a driving mechanism rotating the sputtering cathode unit 60.

The sputtering cathode unit 60 is constituted of a cathode block installed rotatably in a condition that sealing is held by a means such as an O-ring to the vacuum container 2 and plural sputtering cathodes 10 arranged in the cathode block 6. Furthermore, in the cathode block 6, radiation holes 14 are formed corresponding to the sputtering cathodes respectively so as to face the substrate 5. Note that the fringe of each radiation holes 14 is defmed as a hood portion 13. Besides, reference number 40 illustrated in the cathode block 6 indicates pipes for introducing or discharging cooling water for cooling the following cathode base, reference number 50 indicates cathode power cables. Furthermore, the sputtering cathode unit 10 is rotated around a center axis Cc by a driving mechanism 30 which is constituted of an electric motor 31, a driving gear 32 installed on a rotation shaft of the electric motor 31 and a driving gear 33 formed around a shaft of the cathode block 6.

The sputtering cathode 10 is constituted of a cathode base 15, an insulation block 11 provided around the cathode base 15 and insulating between the cathode base 15 and the cathode block 6, a target 7 installed on the cathode base 15 and magnets arranged behind the target 7 and generating magnetic field to the target 7.

Besides, each of the sputtering cathodes 10 is installed to the cathode block 6 so as to regard an axis SPc extending against the substrate 5 as a center axis thereof, and the sputtering cathode unit 60 is installed rotatably so as to regard an axis Cc passing through a center point Cs of the substrate 5 as a center axis thereof. Besides, the center axes Spc cross at a crossing point Pc with the center axis Cc of the sputtering cathode unit 60 and the substrate 5 and pass through each center points Pt of the targets 7. Furthermore, each of the radiation holes extend along the center axes SPc respectively.

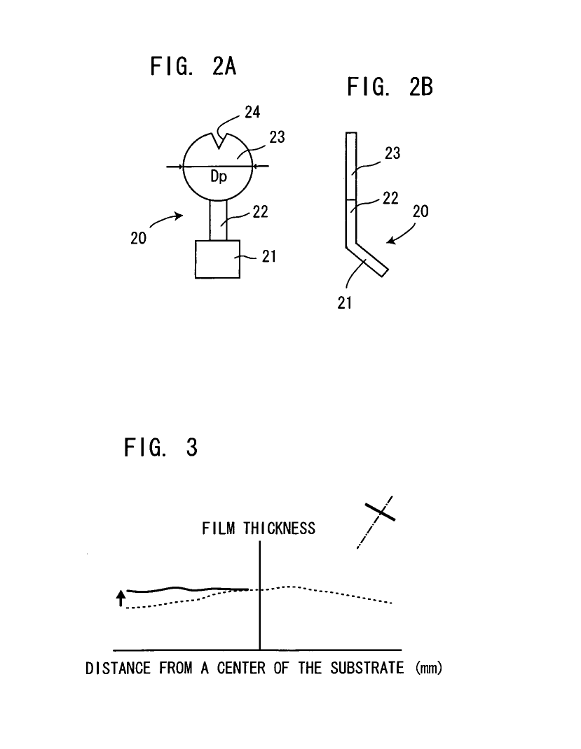

Moreover, distribution modifying plates 20 are arranged in opening end portions of the radiation holes 14 respectively. Each of the distribution modifying plates 20 is, as shown in FIGS. 2A and 2B, constituted of a fixing portion 21 fixed on the cathode block 6, a holding arm portion 22 extending from the fixing portion 21 and a distribution modifying plate portion 23 fixed on the holding arm portion 22. Besides, a specific notch portion 24 is formed at a side of the center axis Cc in the distribution modifying plate portion 23.

Besides, angle a made between the center axis SPc of each sputtering cathodes 10 and the center axis Cc of the sputtering cathode unit 60 is not more than 45°, especially within a range from 15° to 45°.

A distance F between the center point Pt of the target 7 along each of the axes SPc and the point Ps on the substrate 5 is set to about three to four times of a diameter Dt of the target, preferably 2.5 Dt≦F<4.5 Dt. Furthermore, length L of the hood portion 13 is set to the same length as the diameter Dt of the target 7 (L≈Dt). Besides, it is preferred that an opening diameter Do of each radiation holes 14 is set to about 1.5 times of the diameter Dt of the target 7(Do≈1.5 Dt).

Moreover, the substrate holder 4 is arranged so that position of the installed substrate 5 is shifted from the cross point Pc (below with a specific value in this embodiment). Thus, growth of the film thickness in the vicinity of the center point Cs of the substrate is controlled.

Furthermore, a diameter Dp of the distribution modifying plate portion 23 of the distribution modifying plate 20 is set to about half of the diameter Dt of the target 7 (Dp≈0.5 Dt). Optimal film thickness distribution can be achieved by the arrangement under the above numerical limitation.

In the sputtering device 1 with the above constitution, when targets 7 installed on the sputtering cathodes 10 are the same kind and a power source, an exhaust pump and a gas supplying mechanism not shown in figure, and further the driving mechanism 30 are operated, the thin film with good film thickness distribution can be formed on the substrate 7.

Furthermore, as shown in FIG. 3, the distribution modifying plate 20 having the notch portion 24 can promote growth of film thickness at a part far from the target 7, so that film thickness distribution can be further improved.

Hereinafter, embodiment No. 2 is explained, but constitution except for the means for modifying distribution is the same as the above embodiment No. 1, so that explanation for the constitution except for the means for modifying distribution is omitted.

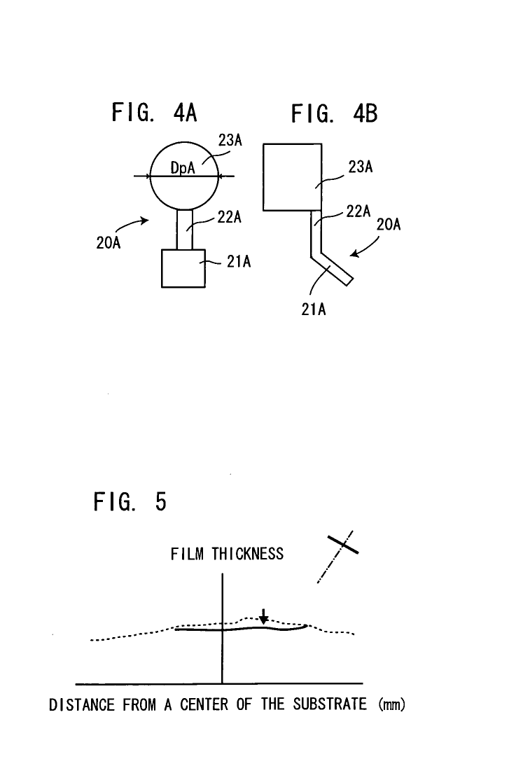

A distribution modifying block 20A as a means for modifying distribution according to the embodiment No. 2 is, for instance, as shown in FIGS. 4A and 4B, constituted of a fixing portion 21A fixed on the cathode block 6, a holding arm portion 22A extending from the fixing portion 21A and a distribution modifying columnar portion 23A fixing to the holding arm portion 22A. A bottom surface diameter DpA of the distribution modifying columnar portion 23A is equal to the diameter Dp of the distribution modifying plate portion 23.

As shown in FIG. 5, according to the distribution modifying block 20A, growth of film thickness in a middle portion of the substrate 5 can be controlled, so that film thickness distribution on the substrate 5 can be further increased.

What is claimed is:

1. A sputtering device comprising at least a vacuum container, a substrate holder arranged in said vacuum container, plural sputtering cathodes each of which has a target for sputtering to a substrate installed on said substrate holder, wherein:
said plural sputtering cathodes are arranged so that center axes of said targets installed on said sputtering cathodes are inclined at specific angle against an axis of said substrate installed on said substrate holder, and
a sputtering cathode unit constituted of said plural sputtering cathodes is held to said vacuum container rotatably around an axis of said substrate.

2. A sputtering device according to claim 1, wherein:
said substrate held on said substrate holder is arranged at a position shifting from a crossing point where said center axes of said targets cross.

3. A sputtering device according to claim 1, wherein:
a hood portion extending with specific length along said axis of said substrate in front of said target is provided, and
a means for modifying distribution is provided on an opening end portion of said hood portion to blockade a specific extent of said opening end portion.

4. A sputtering device according to claim 2, wherein:
a hood portion extending with specific length along said axis of said substrate in front of said target is provided, and
a means for modifying distribution is provided on an opening end portion of said hood portion to blockade a specific extent of said opening end portion.

5. A sputtering device according to claim 3, wherein:
said means for modifying distribution is constituted of a round metal plate having about half a diameter of said target and a support portion supporting said round metal plate, and
a notch portion is formed on a part positioning at a side of said center axis of said substrate.

6. A sputtering device according to claim 4, wherein:
said means for modifying distribution is constituted of a round metal plate having about half a diameter of said target and a support portion supporting said round metal plate, and
a notch portion is formed on a part positioning at a side of said center axis of said substrate.

7. A sputtering device according to claim 3, wherein:
said means for modifying distribution is constituted of a columnar portion having a bottom surface with about half a diameter of said target and extending with specific length along said axis of said target, and a support portion supporting said columnar portion.

8. A sputtering device according to claim 4, wherein:
said means for modifying distribution is constituted of a columnar portion having a bottom surface with about half a diameter of said target and extending with specific length along said axis of said target, and a support portion supporting said columnar portion.

9. A sputtering device according to claim 3, wherein:
said opening end portion of said hood portion has about 1.5 times diameter of said target, and
said hood portion has length similar to said diameter of said target.

10. A sputtering device according to claim 4, wherein:
said opening end portion of said hood portion has about 1.5 times diameter of said target, and
said hood portion has length similar to said diameter of said target.

11. A sputtering device according to claim 5, wherein:
said opening end portion of said hood portion has about 1.5 times diameter of said target, and
said hood portion has length similar to said diameter of said target.

12. A sputtering device according to claim 6, wherein:
said opening end portion of said hood portion has about 1.5 times diameter of said target, and
said hood portion has length similar to said diameter of said target.

13. A sputtering device according to claim 7, wherein:
said opening end portion of said hood portion has about 1.5 times diameter of said target, and
said hood portion has length similar to said diameter of said target.

14. A sputtering device according to claim 8, wherein:
said opening end portion of said hood portion has about 1.5 times diameter of said target, and
said hood portion has length similar to said diameter of said target.

15. A sputtering device according to claim 9, wherein:
each of said sputtering cathodes is that a center axis of each of targets is inclined at angle of 45° against said axis of said substrate installed on said substrate holder, and
distance along said center axis of said target between said target and said substrate is with a range about three to four times of said target's diameter.

16. A sputtering device according to claim 10, wherein:
each of said sputtering cathodes is that a center axis of each of targets is inclined at angle of 45° against said axis of said substrate installed on said substrate holder, and
distance along said center axis of said target between said target and said substrate is with a range about three to four times of said target's diameter.

17. A sputtering device according to claim 11, wherein:
each of said sputtering cathodes is that a center axis of each of targets is inclined at angle of 45° against said axis of said substrate installed on said substrate holder, and
distance along said center axis of said target between said target and said substrate is with a range about three to four times of said target's diameter.

18. A sputtering device according to claim 12, wherein:
each of said sputtering cathodes is that a center axis of each of targets is inclined at angle of 45° against said axis of said substrate installed on said substrate holder, and
distance along said center axis of said target between said target and said substrate is with a range about three to four times of said target's diameter.

19. A sputtering device according to claim 13, wherein:
each of said sputtering cathodes is that a center axis of each of targets is inclined at angle of 45° against said axis of said substrate installed on said substrate holder, and
distance along said center axis of said target between said target and said substrate is with a range about three to four times of said target's diameter.

20. A sputtering device according to claim 14, wherein:
each of said sputtering cathodes is that a center axis of each of targets is inclined at angle of 45° against said axis of said substrate installed on said substrate holder, and
distance along said center axis of said target between said target and said substrate is with a range about three to four times of said target's diameter.
